(19) United States
(12) Patent Application Publication
(10) Pub. No.: US 2009/0233466 A1
(43) Pub. Date: Sep. 17, 2009

(54) SURFACE-MOUNTED CIRCUIT BOARD MODULE AND PROCESS FOR FABRICATING THE SAME

(75) Inventors: Cheng-En Lee, Taoyuan Hsien (TW); Chi-Ming Chin, Taoyuan Hsien (TW)

Correspondence Address: KIRTON AND MCCONKIE, 60 EAST SOUTH TEMPLE,, SUITE 1800, SALT LAKE CITY, UT, 84111, US

(73) Assignee: DELTA ELECTRONICS, INC., Taoyuan Hsien (TW)

(21) Appl. No.: 12/135,108

(22) Filed: Jun. 6, 2008

(30) Foreign Application Priority Data
Mar. 11, 2008 (TW) 097108508

(51) Int. Cl. H01R 12/00; H05K 3/36

(52) U.S. Cl. 439/74; 29/830

(57) ABSTRACT

A surface-mounted circuit board module disposed on a system circuit board is disclosed. The surface-mounted circuit board module comprising a circuit board having at least an electronic component disposed thereon and a plurality of connectors. Each of the connectors comprises a first end portion at least partially embedded in the circuit board, a connecting portion connected with the first portion, and a second end portion extended and bent from the connecting portion. The second end portions are surface mounted on the system circuit board to electrically connect the electronic component of the circuit board and the system circuit board via the connectors.

### FIELD OF THE INVENTION

The present invention relates to a circuit board module and the process for fabricating the same, and more particularly to a surface-mounted circuit board module and the process for fabricating the same.

### BACKGROUND OF THE INVENTION

With the progress of technology, the operation efficiency of the electronic apparatus is raised up. For increasing the operating power and conforming to the trend toward product size minimization, the volume of the electronic apparatus must be reduced and the design of the inner structure is more compacted. In other words, plural circuit board modules have to be disposed on a system circuit board of the electronic apparatus. A connector, for example, a conductive pin, is applied to the circuit board module for the circuit board thereof to be disposed on the system circuit board. The electronic components of the circuit board module can be electrically connected to the system circuit board through the connector.

With reduction of the electronic apparatus volume, the size of the connector has to be correspondingly reduced. Under the prerequisite of not affecting the power density, plural connectors have to be disposed on the circuit board module. The existing circuit board module is disposed on the system circuit board by the connectors thereof inserting into the predetermined through holes of the system circuit board. The circuit board module is further fixed on the system circuit board by soldering the joint of the connector and the through hole. However, each of the connectors has to be precisely aligned with the corresponding through holes of the system circuit board for firmly disposing the circuit board module on the system circuit board. Therefore, the insertion process is complex and time-consuming. Moreover, once the connectors and the through holes are not accurately aligned, the connectors may be damaged during the insertion step. Accordingly, the driving of the circuit board module and the system circuit board are impacted, and the yield of the electronic apparatus is lowered as well.

Therefore, it is required to develop a surface-mounted circuit board module and the process for fabricating the same to overcome the foregoing defects.

### SUMMARY OF THE INVENTION

An object of the present invention is to provide a surface-mounted circuit board module and the process for fabricating the same, so as to avoid the inconvenience of disposing the circuit board module on the system circuit board through inserting manner. The circuit board of the surface-mounted circuit board module comprises connectors. After the connectors are disposed on the circuit board of the surface-mounted circuit board module, the ends of each of the connectors applied to contact with the system circuit board are bent to form the second end portions. Hence the surface-mounted circuit board module can be disposed on the system circuit board by the second end portions of the connectors surface mounting on the system circuit board, and the electronic components on the circuit board of the surface-mounted circuit board module can be electrically connected to the system circuit board via the connectors. Besides, the system circuit board and the second end portion of each of the connectors comprise an included angle therebetween. The included angle is beneficial for the melted solder to exhaust and distribute evenly, so as to prevent the pinhole formation and increase the contact area between the second end portion of the connector and the system circuit board for securely surface mounting the surface-mounted circuit board module on the system circuit board.

According to an aspect of the present invention, a surface-mounted circuit board module disposed on a system circuit board is provided. The surface-mounted circuit board module comprises: a circuit board having at least an electronic component disposed thereon and a plurality of connectors. Each of the connectors comprises a first end portion at least partially embedded in the circuit board, a connecting portion connected with the first end portion, and a second end portion extended and bent from the connecting portion, the second end portion being surface mounted on the system circuit board for the electronic component on the circuit board to be electrically connected to the system circuit board via the connector.

In an embodiment, the circuit board comprises a first side and a second side corresponding to each other, and a plurality of through holes penetrating through the first and second sides of the circuit board for the first end portion of the connector to insert therein.

In an embodiment, the plural connectors are disposed on the first side and the second side of the circuit board, each of the plural connectors further comprises a bent structure formed by the first end portion and the connecting portion, so as to substantially vertically dispose the circuit board on the system circuit board.

In an embodiment, the circuit board further comprises a plurality of pads.

In an embodiment, the plural connectors are disposed on the first side or the second side of the circuit board, the connecting portion of the connector is substantially parallel to the first end portion, so as to substantially parallelly dispose the circuit board on the system circuit board.

In an embodiment, the second end portion of the connector and the system circuit board comprise an included angle therebetween, the range of the included angle is substantially from 0 to 8 degrees.

In an embodiment, the surface-mounted circuit board module further comprises a pick and place component disposed on the circuit board, wherein the pick and place component is a heat sink or a pick and place cap.

In an embodiment, the first end portion, the connecting portion, and the second end portion of each of the plural connectors are integrally formed.

In an embodiment, the circuit board and the system circuit board further comprise a gap therebetween.

According to another aspect of the present invention, there is provided a process for fabricating a surface-mounted circuit board module. The process comprises steps of: (a) providing a circuit board, the circuit board comprising at least an electronic component and a plurality of through holes; (b) providing a plurality of connectors, each of which having a first end portion and a connecting portion connected with the first end portion; (c) inserting the first end portion of the connector into the through hole of the circuit board; (d) bending the end of the connecting portion opposite to that connected with the first end portion to form a second end portion, so as to surface mount the circuit board of the surface-mounted circuit board module on a system circuit board via the second end portion of the connector.

In an embodiment, the step (b) includes sub-step of: (b1) bending the connector to form a bent structure by the first end portion and the connecting portion.

In an embodiment, a bent angle is formed between the connecting portion and the second end portion of the connector, the range of the bent angle is substantially from 90 to 98 degrees.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a flow chart for fabricating the surface-mounted circuit board module according to the first preferred embodiment of the present invention;

FIG. 2A is a schematic diagram showing the surface-mounted circuit board module during assembling according to the first preferred embodiment of the present invention;

FIG. 2B is a schematic diagram showing the finished surface-mounted circuit board module of FIG. 2A being assembling to the system circuit board;

FIG. 2C is the a-a′ cross-section view of FIG. 2B after assembly;

FIG. 3 is a schematic diagram showing the surface-mounted circuit board module disposed on the system board according to the second preferred embodiment of the present invention;

FIG. 4 is a schematic diagram showing the surface-mounted circuit board module disposed on the system board according to the third preferred embodiment of the present invention;

FIG. 5 is a flow chart for fabricating the surface-mounted circuit board module according to the fourth preferred embodiment of the present invention;

FIG. 6A is a schematic diagram showing the surface-mounted circuit board module of the fourth preferred embodiment of the present invention being assembling to the system circuit board; and

FIG. 6B is a b-b′ cross-section view of FIG. 6A after assembly.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

The surface-mounted circuit board module of the present invention is disposed on a system circuit board of an electronic apparatus (figure not shown) by surface mount technology (SMT). The surface-mounted circuit board module of the present invention can be a power module or any other similar module, but not limited thereto.

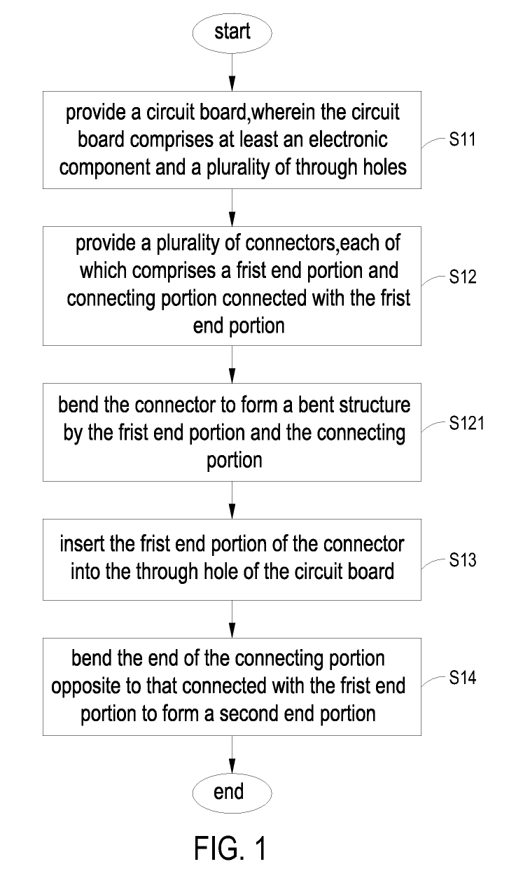

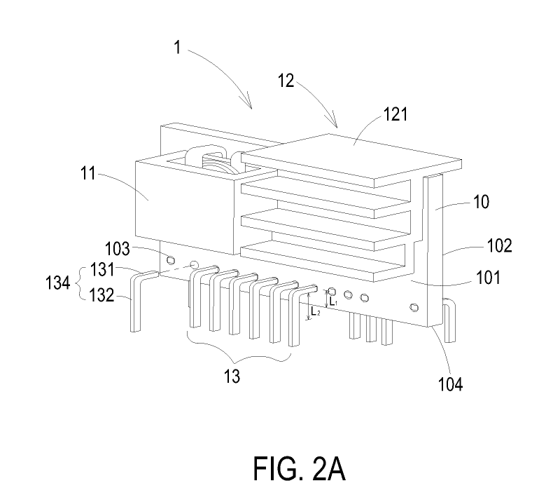

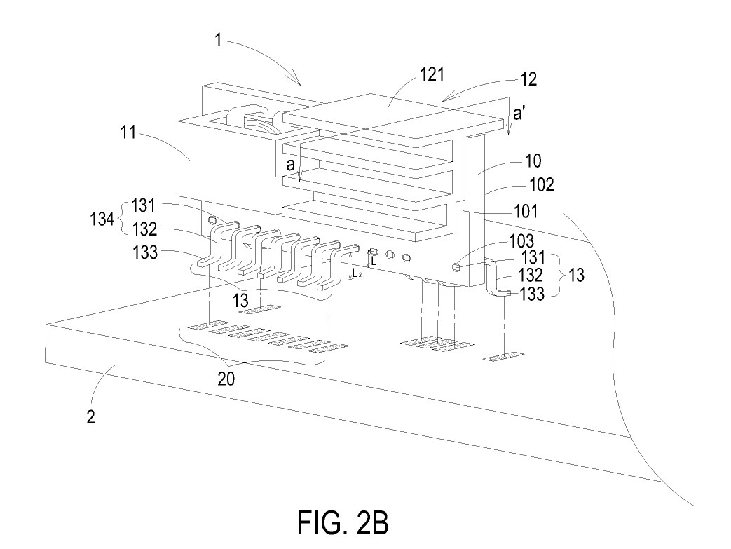

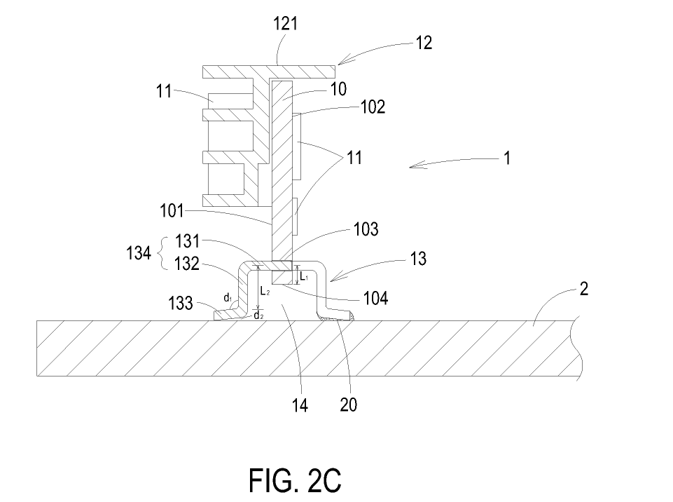

Please refer to FIG. 1 and FIG. 2A, which are respectively the flow chart for fabricating the surface-mounted circuit board module and the schematic diagram showing the surface-mounted circuit board module during assembling according to the first preferred embodiment of the present invention. For fabricating the surface-mounted circuit board module 1, a circuit board 10 is provided (step S11). The circuit board 10 has a first side 101 and a second side 102, wherein the first side 101 and the second side 102 are corresponding to each other. The circuit board 10 further comprises plural through holes 103, which substantially vertically penetrate through the first side 101 and the second side 102 of the circuit board 10 (as shown in FIG. 2C). The shape of the through hole 103 is preferred to be circular, but not limited thereto. The distance from the through hole 103 to the nearest edge 104 adjacent thereto is L1. Conductive layers (not shown) for connecting to the trace (not shown) of the circuit board 10 can be coated at the inner sidewall of each of the through holes 103.

The circuit board 10 further comprises at least an electronic component 11 and a pick and place component 12 disposed thereon. In this embodiment, the circuit board 10 comprises plural electronic components 11. The electronic components 11 can be the components such as inductance, capacitance, and etc., which can be disposed on the first side 101 and/or the second side 102 of the circuit board 10. The pick and place component 12 has a flat surface 121 across the first side 101 and the second side 102 of the circuit board 10. In this embodiment, the pick and place component 12 can be a heat sink, such as an aluminum extrusion heat sink, that fixed on the circuit board 10 through adherent media like thermal adhesive etc.

Plural connectors 13 are also provided to fabricate the surface-mounted circuit board module 1 (step S12), wherein the connectors 13 can be derived from the carrier tape (not shown). Each of the connectors 13 comprises a first end portion 131 and a connecting portion 132, wherein the connecting portion 132 is connected to and extended from the first end portion 131. In this embodiment, connectors 13 are composed of uniform rod-like conductive material, such as copper, aluminum, and etc. The shape of the cross-section of the connector 13 is preferred to be rectangular, wherein the length of the diagonal of the rectangular cross-section is approximately equal to the diameter of the through hole 103 of the circuit board 10 (as shown in FIG. 2B), but not limited thereto as well. Subsequently, the connectors 13 are bent by a jig (not shown), so as to form a bent structure 134 by the first end portion 131 and the connecting portion 132 (step S121). In this embodiment, the first end portion 131 of the connector 13 is perpendicular to the connecting portion 132. In other words, the first end portion 131 and the connecting portion 132 form a 90 degree bent structure 134, and the connector 13 at this time is substantially an L-shape (as shown in FIG. 2A).

Next, each of the connectors 13 is corresponded to one of through holes 103, and parts of connectors 13 are connected to the circuit board 10 by the first end portions 131 thereof inserted into the through holes 103 from the first side 101 of the circuit board 10. The other parts of the connectors 13 are connected to the circuit board 10 by the first end portions 131 thereof inserted into the through holes 103 from the second side 102 of the circuit board 10 (step S13). Therefore, the connectors 13 can be disposed on the first side 101 and the second side 102 of the circuit board 10. In other words, the connectors 13 are not symmetrically disposed on the first side 101 and the second side 102 of the circuit board 10. Beside, since the diagonal length of the cross-section of the connector 13 is substantially equal to the diameter of the through hole 103 of the circuit board 10, the first end portion 131 of the connector 13 can be firmly engaged with the through hole 103.

In this embodiment, each of the first end portions 131 of the connectors 13 is partially inserted into each of the through holes 103. That is to say, only a part of the first end portion 131 of each of the connectors 13 is embedded in the circuit board 10, whereas the rest of the first end portion 131 is exposed outside of the circuit board 10. The length of the exposed first end portion 131 is substantially equal to half of the height of the tallest electronic component 11 disposed on the side of the circuit board 10 where the connector 13 being disposed, so as to adjust gravity center of the circuit board 10 according to the disposition of the electronic components 11. For example: when an electronic component 11 with larger volume is disposed on the first side 101 of the circuit board 10, a longer first end portion 131 of the connector 13 can be reserved in step S121. Thus when the connector 13 is inserted into the through hole 103 in step S13 from the first side 101 of the circuit board 10, a relative longer first end portion 131 is exposed outside of the circuit board 10 for adjusting the gravity center of the circuit board 10, so as to avoid the collapse of the circuit board 10 when the circuit board 10 is disposed on the system circuit board 2. Of course, in some embodiment, if the gravity center adjustment of the circuit board 10 is not taken into consideration, the length of the first end portion 131 can be reduced, and the whole first end portion 131 of each of the connectors 13 can be inserted into the through hole 103 for the connecting portion 132 to be extended directly from the circuit board 10.

In addition, step S13 of the present invention can be processed by an automatic pin insertion machine (not shown). Of course, in some embodiment, a soldering process can be performed at the through hole 103 after step S13 to ensure the connection between the connector 13 and the circuit board 10. Since the circular through hole 103 and the first end portion 131 of the connector 13 with rectangular cross-section have space formed therebetween, the melted solder can exhaust through the space to minimize the formation of pinhole during the soldering period. Hence the current resistance and impact on the electric conductive effect caused by the pinhole can be avoided. As regards the circuit board module after the completion of step S13 can be disposed on a system circuit board having through holes by the connecting portions directly inserted into the through holes.

Please refer to FIG. 1, FIG. 2B and FIG. 2C, wherein FIG. 2B is the finished surface-mounted circuit board module of FIG. 2A being assembling to the system circuit board and FIG. 2C is the a-a′ cross-section view of FIG. 2B after assembly. As shown in these figures, after step S13 is finished, an adjustment procedure for bending the connectors 13 is performed by jig (not shown). In other words, plural connectors 13 coupled to the circuit board 10 are bent. A length L2 of the connecting portion 132 is reserved, and the end of the connecting portion 132 opposite to that connected with the first end portion 131 is bent toward the direction away from the circuit board 10, so as to form the second end portion 133 (step S14). That is to say, the second end portion 133 of the connector 13 is extended and bent from the connecting portion 132 (as shown in FIG. 2B). In this embodiment, each of the connectors 13 is integrally formed, wherein the first end portion 131, the connecting portion 132, and the second end portion 133 thereof are formed by bending. Since the second end portions 133 of the connectors 13 disposed on the first side 101 of the circuit board 10 are simultaneously bent by the jig (not shown), the second end portions 133 can be flatly formed on the same plane. Of course, the second end portions 133 of the connectors 13 disposed on the second side 102 of the circuit board 10 are also simultaneously bent, and thus the coplanar second end portions 133 can be flatly formed. After the adjustment procedure of step S14 is finished, the surface-mounted circuit board module 1 as shown in FIG. 2B can be obtained.

Please refer to FIG. 2B and FIG. 2C again. In this embodiment, a bent angle d1 is formed between the second end portion 133 and the connecting portion 132 on every connector 13 of the surface-mounted circuit board module 1. The degree of the bent angle d1 is substantially 90 to 98 degrees, preferably 93 to 95 degrees, but not limited thereto. Moreover, the length L2 of the connecting portion 132 is larger than the distance L1 from the through hole 103 to the edge 104. Thus, when each of the connectors 13 is disposed on the circuit board 10, part of the connecting portion 132 and the second end portion 133 are protruded relative to the edge 104 of the circuit board 10 (as shown in FIG. 2C), so the surface-mounted circuit board module 1 can contact to the system circuit board 2 via the second end portion 133 of each of the connectors 13.

While disposing the surface-mounted circuit board module 1 on the system circuit board 2 of an electronic apparatus (not shown), a pick and place machine (not shown) can be used to draw the flat surface 121 of the pick and place component 12 to place the surface-mounted circuit board module 1 on the predetermined position of the system circuit board 2. The second end portion 133 of each of the connectors 13 therefore contacts with the conductive areas 20 of the system circuit board 2, wherein the conductive areas 20 are coated with solder. The circuit board 10 is substantially perpendicular to the system circuit board 2 at this time. Since the first end portion 131 of the connector 13 is inserted into the through hole 103 perpendicular to the circuit board 10, the first end portion 131 is approximately perpendicular to the connecting portion 132, and the connecting portion 132 and the second end portion 133 have a bent angle d1 ranging from 90-98 degrees therebetween, an included angle d2 is formed between the second end portion 133 of the connector 13 and the system circuit board 2 when the circuit board 10 is disposed on the system circuit board 2 (as shown in FIG. 2C). The included angle d2 substantially ranges from 0 to 8 degrees, preferably 3 to 5 degrees, but not limited thereto. While the surface-mounted circuit board module 1 and the system circuit board 2 and reflowed in the reflow oven, the melted solder on the conductive area 20 can fill the space between the second end portion 133 of the connector 13 and the system circuit board 2 by capillary phenomenon. Therefore, the solder can be uniformly distributed, so as to increase the contact area between the second end portion 133 and the system circuit board 2 and enhance the structural strength therebetween. In addition, the included angle d2 is advantageous for the melted solder to exhaust, so as to avoid the formation of holes, such as pinholes, and prevent the impact on conductive effect caused by the hole formation. Moreover, the gravity center of the circuit board 10 can be adjusted by the disposition of the pick and place component 12 and the modulation of the length of the first end portion 131 of the connector 13 exposed relative to the circuit board 10. Thus even the circuit board 10 of the surface-mounted circuit board module 1 with plural electronic components 11 is vertically disposed on the system circuit board 2, the collapse of the surface-mounted circuit board module 1 due to the off balance can be prevented by the design of the present invention. In such way, the surface-mounted circuit board module 1 can be firmly disposed on the system circuit board 2 via the second end portions 133 of the connectors 13 surface mounted on the system circuit board 2, and the electronic components 11 on the circuit board 10 can be electrically connected to the system circuit board 2 through the connectors 13. Nevertheless, to clearly illustrate the included angle d2 between the second end portion 133 of the connector 13 and the system circuit board 2, solder that filled the space between the system circuit board 2 and the second end portion 133 of the connector 13 on the left of FIG. 2C is not shown.

Please refer to FIG. 2B and FIG. 2C again, since the length L2 of the connecting portion 132 is larger than the distance L1 from the through hole 103 to the edge 104 of the circuit board 10, a gap 14 can be created between the edge 104 of the circuit board 10 and the system circuit board 2. When the electronic apparatus (not shown) is bumped or shocked, the gap 14 can not only provide cushion effect to avoid the loosening of the surface-mounted circuit board module 1 from the system circuit board 2 that may affect the efficiency of the electronic apparatus but also keep space for the layout of the system circuit board 2.

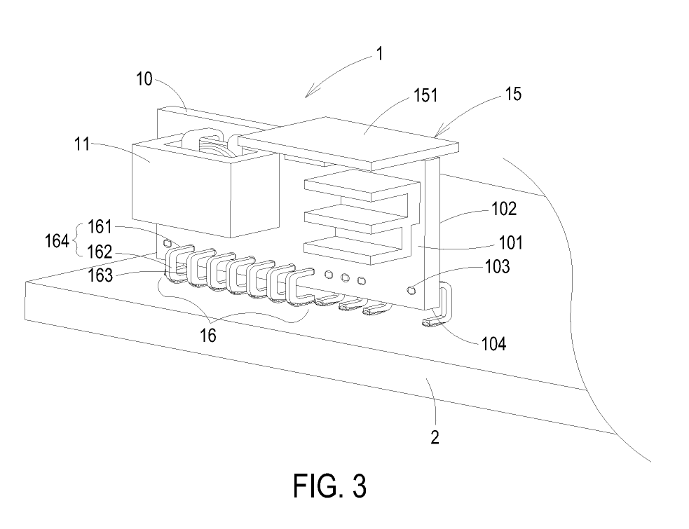

Please refer to FIG. 3, which is a schematic diagram showing the surface-mounted circuit board module disposed on the system circuit board according to the second preferred embodiment of the present invention. The surface-mounted circuit board module 1 is perpendicularly disposed on the system circuit board 2. The circuit board 10 has electronic components 11, pick and place component 15 and plural connectors 16 disposed thereon, wherein the disposition of the electronic components 11 is the same as that shown in FIG. 2B. The pick and place component 15 in this embodiment is preferred to be a pick and place cap that has a flat surface 151 across the first side 101 and the second side 102 of the circuit board 10, so as to draw the flat surface 151 to place the surface-mounted circuit board module 1 on the predetermined position of the system circuit board 2 by the automatic pick and place machine (not shown). The pick and place component 15 can be removed from the circuit board 10 after the surface-mounted circuit board module 1 is disposed on the system circuit board 2. In other words, the pick and place component 15 can be a disposable pick and place cap, but not limited thereto.

In addition, the connectors 16 are processed according to the flow chart shown in FIG. 1. Each of the connector 16 is bent in step S121 to form the bent structure 164 by the first end portion 161 and the connecting portion 162. However, the second end portion 163 on every connector 16 is bent toward the circuit board 10 in step S14 to make the connectors 16 as square bracket shape. The relationships among the first end portion 161, the connecting portion 162, and the second end portion 163 of the connector 16 and the relationships among the connector 16, the circuit board 10 and the system circuit board 2 are similar to that shown in FIG. 2B and FIG. 2C, and thus it is not redundantly described.

According to the foregoing descriptions and incorporated with FIG. 2C and FIG. 3, it is to be understood that the angles between the first end portion and the connecting portion and between the connecting portion and the second end portion of the connector are not limited, and the methods to form the bent structure and the bent angle of the connector are not limited as well. The first end portion, the connecting portion, and the second end portion of the connector can be bent as a Z-shape (as shown in FIG. 2C) or a square bracket shape (as shown in FIG. 3) depending on user's requirements. In other words, the method of bending the connectors to form the first end portions and the connecting portions first, and then forming the second end portions by bending the connectors after the connectors being disposed on the circuit board for each of the second end portions to form an included angle of 0-8 degrees with the system circuit board while the surface-mounted circuit board module being surface mounted on the system circuit board belongs to the concept of the present invention.

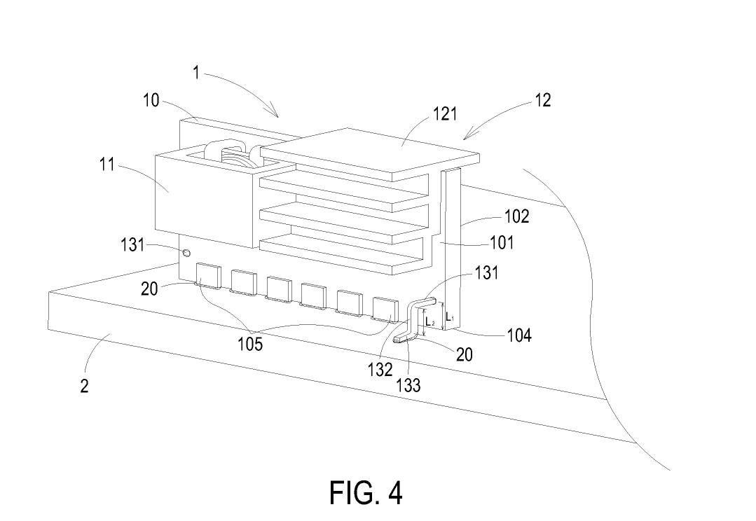

Please refer to FIG. 4, which is a schematic diagram showing the surface-mounted circuit board module disposed on the system board according to the third preferred embodiment of the present invention. The structure of the surface-mounted circuit board module 1 is similar to that of the first preferred embodiment shown in FIG. 2B. However, in this embodiment, the circuit board 10 of the surface-mounted circuit board module 1 further comprises plural pads 105 electrically conducted to the trace (not shown) of the circuit board 10. The pads 105 are disposed on the first side 101 and/or the second side 102 near the edge 104 of the circuit board 10. The length L2 of the connecting portion 132 of the connector 13 is substantially equal to the distance L1 from the through hole 103 to the edge 104 of the circuit board 10. Thus the second end portion 133 of each of the connectors 13 is approximately coplanar with the edge 104 of the circuit board 10.

When the surface-mounted circuit board module 1 is disposed on the system circuit board 2, the edge 104 of the circuit board 10 leans against the surface of the system circuit board 2 for the pads 105 on the circuit board 10 and the second end portion 133 of the connector 13 to contact with the conductive area 20 on the system circuit board 2. Since solder is coated on the conductive area 20, the circuit board 10 of the surface-mounted circuit board module 1 can be surface mounted on the system circuit board 2 via the pads 105 and the connectors 13 after reflow procedure, so as to electrically connect the electronic components 11 and the system circuit board 2. In this embodiment, the electronic components 11 can be electrically connected to the system circuit board 2 via the pads 105, and thus the connectors 13 can be replaced by non-conductive material to serve as supporting structures to prevent the surface-mounted circuit board module 1 from collapsing while the electronic apparatus is bumped or shocked.

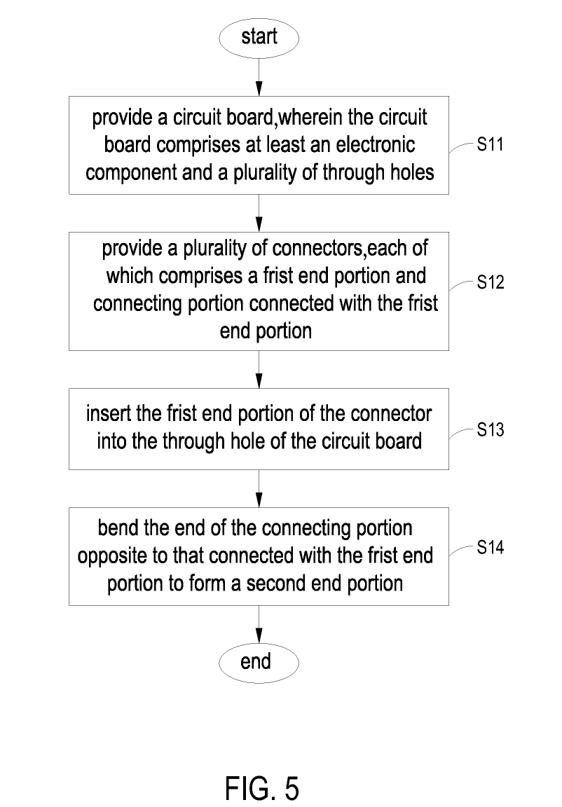

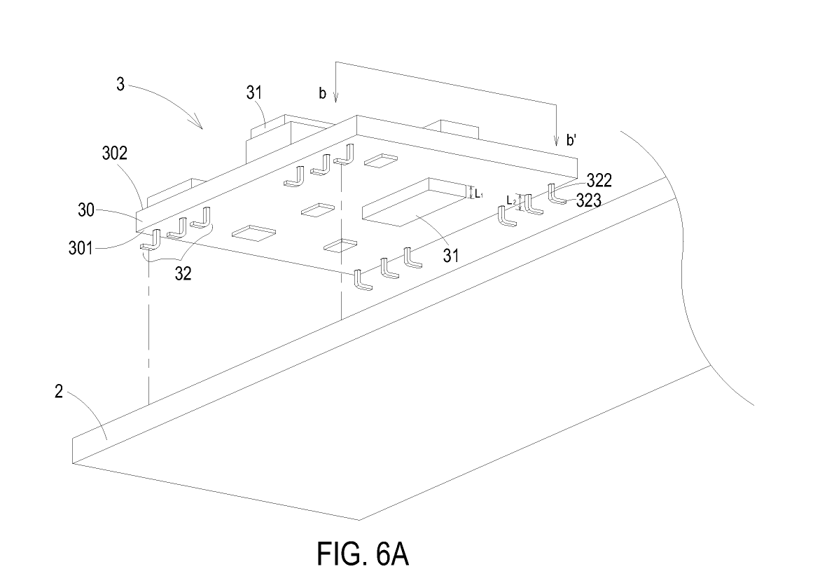

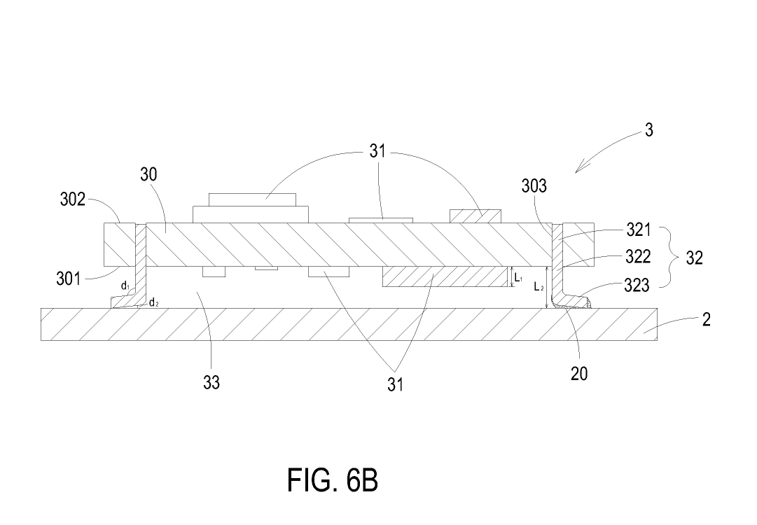

Of course, the present invention is not limited to the foregoing embodiments. FIG. 5 is a flow chart for fabricating the surface-mounted circuit board module according to the fourth preferred embodiment of the present invention, and FIG. 6A and FIG. 6B are schematic diagrams respectively showing the surface-mounted circuit board module being assembling to the system circuit board and the b-b′ cross-section view of FIG. 6A after assembly. Please refer to FIG. 5, FIG. 6A and FIG. 6B, a circuit board 30 is provided to fabricate the surface-mounted circuit board module 3 (step S11). The circuit board 30 has a first side 301 and a second side 302 corresponding to each other. The circuit board 30 further comprises plural through holes 303 substantially vertically penetrate through the first side 301 and second side 302 (as shown in FIG. 6B). The shape of the through hole 303 is preferred to be circular, but not limited thereto. In addition, electronic components 31 are disposed on the first side 301 and second side 302 of the circuit board 30, wherein the electric components 31 can be inductance, capacitance, and etc., but not limited thereto.

Subsequently, plural connectors 32 are provided. Each of the connectors 32 has a first end portion 321 and a connecting portion 322 connected with the first end portion 321 (step S12). In this embodiment, the connectors 32 are composed of uniform rod-like conductive material. The cross-section of each of the connectors 32 is preferred to be rectangular, wherein the length of the diagonal of the cross-section is approximately equal to the diameter of the through hole 303 of the circuit board 30. As regards the connecting portion 322 is parallel to the first end portion 321. In other words, the connecting portion 322 is extended from the first end portion 321 and coplanar with the first end portion 321 to form the connecting portion 322 and the first end portion 321 as a straight linear shape (as shown in FIG. 6B). Besides, the connectors 32 can be derived from the metal continuous reel (not shown).

Next, the first end portion 321 of each of the connectors 32 is inserted into the though hole 303 of the circuit board 30 (step S13). In this embodiment, the first end portion 321 of each of the connectors 32 is inserted into the through hole 303 from the first side 301 of the circuit board 30, and thus the connectors 32 are extended only from one side. Since the length of the diagonal of the rectangular cross-section of the connector 32 is substantially the same as the diameter of the through hole 303 of the circuit board 30, the connectors 32 can be firmly fixed in the through holes 303 of the circuit board 30.

After all the connectors 32 are inserted in the through holes 303 via the first end portions 321, the connectors 32 are processed by a jig (not shown) to bend the end of the connecting portion 322 opposite to that connected to the first end portion 321 to form a second end portion 323 (step S14). In other words, the second end portion 323 is extended and bent from the connecting portion 322 of the connector 32. In this embodiment, the length of the connecting portion 322 of the connector 32 is L2, which is larger than the height L1 of the tallest electronic component 31 on the first side 301 of the circuit board 30. The connecting portion 322 and the second end portion 323 comprise a bent angle d1 therebetween (as shown in FIG. 6B). The bent angle d1 substantially ranges from 90 to 98 degrees, preferably 93 to 95 degrees, but not limited thereto. After the second end portion 323 is processed, the surface-mounted circuit board module 3 shown in FIG. 6A can be obtained. Since the second end portions 323 are bent (step S14) after the linear connectors 32 are inserted into the though holes 303 of the circuit board 30 (step S13), the flatness of the second end portions 323 of the connectors 32 can be ensured.

Similarly, the surface-mounted circuit board module 3 can be placed on the system circuit board 2 with the first side 301 of the circuit board 30 facing the system circuit board 2 by an automatic pick and place machine (not shown). Since the connectors 32 are disposed on and extended from the first side 301 of the circuit board 30, the surface-mounted circuit board module 3 can be disposed on the system circuit board 2 through the second end portions 323 of the connectors 32 contacting with the conductive areas 20 of the system circuit board 2. Under this circumstance, the circuit board 30 of the surface-mounted circuit board module 3 is parallel to the system circuit board 2. In comparison with the surface-mounted circuit board module 1 shown in FIG. 2B, the electronic component 31 on the second side 302 of the circuit board 30 is applied as the pick and place component in this embodiment. That is to say, the automatic pick and place machine (not shown) draws the larger flat surface of the electronic component 31 on the second side 302 of the circuit board 30, so as to pick and place the surface-mounted circuit board module 3.

Since the first end portion 321 of the connector 32 is vertically embedded in the circuit board 30, the connecting portion 322 is parallel to the first end portion 321, and the second end portion 323 and the connecting portion 322 have the bent angle d1 therebetween, an included angle d2 will be created between the second end portion 323 and the system circuit board 2 while the surface-mounted circuit board module 3 is disposed on the system circuit board 2. The included angle d2 ranges from 0 to 8 degrees, preferably 3 to 5 degrees, but not limited thereto. In addition, the conductive area 20 in contact with the second end portion 323 can be coated with solder. Therefore, the space between the second end portion 323 of the connector 32 and the system circuit board 2 can be filled with melted solder owing to the capillary phenomenon during soldering process. The included angle d2 between the second end portion 323 and the system circuit board 2 is not only advantageous for increasing the contact area between the second end portion 323 and the system circuit board 2 but also advantageous for exhausting. Thus the increase of current resistance and impact on conductive efficiency caused by the pinhole formation can be prevented. Accordingly, the surface-mounted circuit board module 3 can be firmly surface mounted on the system circuit board 2 via the second end portions 323 of every connector 32, and the electronic components 31 on the circuit board 30 can be electrically connected to the system circuit board 2 through the connectors 32.

Please refer to FIG. 6B again. Because the length L2 of the connecting portion 322 of the connector 32 is larger than the height L1 of the tallest electronic component 31 on the first side 301 of the circuit board 30, a gap 33 can be created between the circuit board 30 and the system circuit board 2. The gap 33 is beneficial to cushion the impact and lower the layout limitation of the system circuit board 2. Please be advised that for clearly illustrating the included angle d2 between the second end portion 323 and the system circuit board 2, the solder filled between the system circuit board 2 and the second end portion 323 of the connector 32 on the left of FIG. 6B is not shown.

Of course, in some embodiments, the first end portions 321 of the connectors 32 can be inserted into the through holes 303 of the circuit board 30 from the second side 302. The connectors 32 therefore are disposed on and extended from the second side 302. Under this circumstance, the circuit board 30 of the surface-mounted circuit board module 3 can be parallelly disposed on the system circuit board 2 with the second side 302 thereof facing the system circuit board 2.

According to the foregoing descriptions, it is to be understood that the manner the surface-mounted circuit board module disposed on the system circuit board can be adjusted by slightly modifying the process for fabricating the surface-mounted circuit board module. For example, when fabricating the surface-mounted circuit board module 1, each of the connectors 13 is bent to form the bent structure 134 by the first end portion 131 and the connecting portion 132 first. Then the first end portions 131 of the connectors 13 are inserted into the through holes 103 from the first side 101 and the second side 102 of the circuit board 10. The connectors 13 are subsequently bent to form the second end portions 133, so as to dispose the circuit board 10 of the surface-mounted circuit board module 1 on the system circuit board 2 perpendicularly (as shown in FIG. 2C, FIG. 3, and FIG. 4). If the first end portion 321 and the connecting portion 322 of every connector 32 are parallel and coplanar, the connectors 32 are inserted into the through holes 303 from the first side 301 or the second side 302 of the circuit board 30, and then the connectors 32 are bent to form the second end portions 323, the circuit board 30 of the surface-mounted circuit board module 3 can be parallelly disposed on the system circuit board 2 via the connectors 32 (as shown in FIG. 6B). Hence the surface-mounted circuit board module can be flexibly disposed on the system circuit board depends on the layout of the system circuit board.

When the circuit board of the surface-mounted circuit board module is desired to be perpendicularly disposed on the system circuit board (as shown in FIG. 2C, FIG. 3, and FIG. 4), the length of the first end portion of the connector can be adjusted in step S121, and the first end portion of each connectors can be partially inserted into the through holes of the circuit board in step S13. Thus the gravity center of the circuit board can be adjusted by the exposed first end portion of each of the connectors to avoid the collapse of the circuit board.

Besides, in the present invention, an included angle d2 with the range of 0 to 8 degrees is formed between the second end portion of the connector of the surface-mounted circuit board module and the system circuit board (as shown in FIG. 2C and FIG. 6B). Hence the solder can exhaust and fill the space between the second end portion and the system circuit board evenly and entirely, so as to reduce the pinhole formation and increase the contact area between the second end portion and the system circuit board.

In some embodiments, the length of the connecting portion of the connector of the surface-mounted circuit board module can be adjusted in steps S12 or S121, so as to form a cushion gap between the circuit board and the system circuit board while the surface-mounted circuit board module is disposed on the system circuit board (as shown in FIG. 2C, FIG. 3, and FIG. 6B). Moreover, since the circuit board of the surface-mounted circuit board module is elevated disposed on the system circuit board, the space on the system circuit board is not occupied by the surface-mounted circuit board module. Thus the layout of the system circuit board will not be limited with the disposition of the surface-mounted circuit board module.

In some embodiments of the present invention, the gravity center of the circuit board of the surface-mounted circuit board module can be adjusted by disposing a pick and place component (as shown in FIG. 2B, FIG. 3, and FIG. 4). Furthermore, if the pick and place component is a heat sink, it is not necessary to remove the heat sink after the surface-mounted circuit board module is disposed on the system circuit board. The heat dissipating effect of the surface-mounted circuit board module can be further raised by keeping the heat sink on the circuit board.

To sum up, the surface-mounted circuit board module is surface mounted on the system circuit board by the second end portions of the connectors. Therefore, the inconvenience for inserting the connectors into the through holes of the system circuit board can be prevented. In addition, the surface-mounted circuit board module can be vertically or horizontally disposed on the system circuit board by modifying the shape of the connectors and the manner that the connectors being inserted into the circuit board. So the disposition of the surface-mounted circuit board module is more flexible. Moreover, since the second end portions of the connectors are bent after the connectors are coupled to the circuit board and after the circuit board is tested, the flatness of the second end portions can be ensured and the impact to the flatness of the second end portions caused by the test can be reduced.

Furthermore, the soldering area between the second end portion of the connector and the system circuit board can be increased and gas in the melted solder can be exhausted through the included angle d2, so as to fortify the structural strength between the surface-mounted circuit board module and the system circuit board and prevent the formation of the pinhole. The cushion gap between the circuit board and the system circuit board can be created by adjusting the length of the connecting portion of the connector. Whereas the gravity center of the circuit board can be revised by modifying the length of the first end portion of the connector or disposing the pick and place component. All the foregoing features are advantageous for the surface-mounted circuit board module to be firmly and securely surface mounted on the system circuit board.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A surface-mounted circuit board module disposed on a system circuit board, said surface-mounted circuit board module comprising:
a circuit board having at least an electronic component disposed thereon, said circuit board and said system circuit board further comprising a gap therebetween; and
a plurality of connectors, each of which comprising:
a first end portion at least partially embedded in said circuit board;
a connecting portion connected with said first end portion; and
a second end portion extended and bent from said connecting portion, said second end portion being surface mounted on said system circuit board for said electronic component on said circuit board to be electrically connected to said system circuit board via said connector.

2. The surface-mounted circuit board module according to claim 1, wherein said circuit board comprises:
a first side and a second side corresponding to each other; and
a plurality of through holes penetrating through said first side and said second side of said circuit board for said first end portion of said connector to insert therein.

3. The surface-mounted circuit board module according to claim 2, wherein said plurality of connectors are disposed on said first side and said second side of said circuit board, each of said plurality of connectors further comprises a bent structure formed by said first end portion and said connecting portion, so as to substantially vertically dispose said circuit board on said system circuit board.

4. (canceled)

5. The surface-mounted circuit board module according to claim 2, wherein said plurality of connectors are disposed on said first side or said second side of said circuit board, said connecting portion of said connector is substantially parallel to said first end portion, so as to substantially parallelly dispose said circuit board on said system circuit board.

6. The surface-mounted circuit board module according to claim 1, wherein said second end portion of said connector and said system circuit board comprise an included angle therebetween, the range of said included angle is substantially from 0 to 8 degrees.

7. The surface-mounted circuit board module according to claim 1 further comprising a pick and place component disposed on said circuit board.

8. The surface-mounted circuit board module according to claim 7, wherein said pick and place component is a heat sink or a pick and place cap.

9. The surface-mounted circuit board module according to claim 1, wherein said first end portion, said connecting portion, and said second end portion of each of said plurality of connectors are integrally formed.

10. (canceled)

11. A process for fabricating a surface-mounted circuit board module, comprising steps of:
(a) providing a circuit board, said circuit board comprising at least an electronic component and a plurality of through holes;
(b) providing a plurality of connectors, each of which having a first end portion and a connecting portion connected with said first end portion;
(c) inserting said first end portion of said connector into said through hole of said circuit board;
(d) bending the end of said connecting portion opposite to that connected with said first end portion to form a second end portion, so as to surface mount said circuit board of said surface-mounted circuit board module on a system circuit board via said second end portion of said connector.

12. The process according to claim 11, wherein said circuit board comprising a first side and a second side, said plurality of through holes penetrate through said first side and said second side of said circuit board.

13. The process according to claim 12, wherein the step (b) includes sub-step of: (b1) bending said connector to form a bent structure by said first end portion and said connecting portion.

14. The process according to claim 13, wherein in the step (c) said plurality of connectors are inserted into said plurality of through holes from said first side and said second side of said circuit board, so as to dispose said plurality of connectors on said first side and said second side of said circuit board.

15. The process according to claim 12, wherein said connecting portion is substantially parallel to said first end portion of said connector.

16. The process according to claim 15, wherein in the step (c) said plurality of connectors are inserted into said plurality of through holes from said first side or said second side of said circuit board, so as to dispose said plurality of connectors on said first side or said second side of said circuit board.

17. The process according to claim 11, wherein in the step (d) a bent angle is formed between said connecting portion and said second end portion of said connector, the range of said bent angle is substantially from 90 to 98 degrees.

18. The process according to claim 11, wherein said circuit board further has a pick and place component disposed thereon.

19. The process according to claim 18, wherein said pick and place component is a heat sink or a pick and place cap.

20. The process according to claim 11, wherein said first end portion, said connecting portion, and said second end portion of each of said plurality of connectors are integrally formed.
